(19) United States
(12) Patent Application Publication
(10) Pub. No.: US 2025/0072042 A1
(43) Pub. Date: Feb. 27, 2025

(54) ELECTROSTATIC DISCHARGE PROTECTION DEVICE

(71) Applicant: UNITED MICROELECTRONICS CORP., Hsin-chu City (TW)

(72) Inventors: Tzu-Hsin Chen, Yilan County (TW); Mei-Ling Chao, Tainan City (TW); Tien-Hao Tang, Hsinchu City (TW); Kuan-cheng Su, Taipei City (TW)

(73) Assignee: UNITED MICROELECTRONICS CORP., Hsin-chu City (TW)

(21) Appl. No.: 18/376,450

(22) Filed: Oct. 4, 2023

(30) Foreign Application Priority Data
Aug. 23, 2023 (TW) 112131645

(51) Int. Cl. H01L 29/78; H01L 27/02; H01L 29/06; H01L 29/08

(52) U.S. Cl. CPC H01L 29/7816; H01L 27/027; H01L 29/0653; H01L 29/0878

(57) ABSTRACT

An electrostatic discharge protection device includes a substrate, a well region of a first conductivity type in the substrate, a drain field region and a source field region of a second conductivity type in the well region, a gate structure on the well region and between the drain field region and the source field region, a drain contact region and a source contact region of the second conductivity type respectively in the drain field region and the source field region, a first isolation region in the drain field region and between the drain contact region and the gate structure, and a drain doped region of the first conductivity in the drain field region and between a portion of a bottom surface of the drain contact region and the drain field region.

### BACKGROUND OF THE INVENTION

### 1. Field of the Invention

The present invention relates to a semiconductor device. More particularly, the present invention relates to an electrostatic discharge protection device.

### 2. Description of the Prior Art

Electrostatic discharge (ESD) is a sudden discharge process of accumulated electrostatic charges. Generally, ESD events occurring in integrated circuit chips include human body mode (HBM) and machine model (MM), which may cause irreversible damages to the internal circuits when the fast, transient and high voltage ESD currents enter the internal circuits through the input/output (I/O) pads.

A practical method used in the industry to reduce ESD damages is coupling ESD protection devices between the I/O pads and the internal circuits. Once an ESD event occurs, the ESD protection devices may be immediately triggered to bypass and release the ESD currents to the ground instead of injecting into the internal circuits, so that the internal circuits may be well protected from damages caused by ESD currents.

Currently, the ESD protection devices must pass HBM stress test at 2 kV and MM stress test at 200V to be qualified for industry application. However, the technical requirements for ESD protection devices used in advanced technology have become more and more critical as the design complexities of integrated circuit increase. There is still a need in the field to provide an ESD protection device which must be able to be triggered immediately when an ESD event occurs to immediately release ESD current, and must pass HBM stress test at least at 2 kV and MM stress test at least at 200V.

### SUMMARY OF THE INVENTION

The present invention is directed to provide an electrostatic discharge (ESD) protection device having improved triggering efficiency and reliability to meet the needs of advanced technology.

One embodiment of the present invention provides an electrostatic discharge protection device, which includes a substrate, a well region of a first conductivity type in the substrate, a drain field region and a source field region of a second conductivity type in the well region, a gate structure on the well region and between the drain field region and the source field region, a drain contact region and a source contact region of the second conductivity type respectively in the drain field region and the source field region, a first isolation region in the drain field region and between the drain contact region and the gate structure, and a drain doped region of the first conductivity in the drain field region and between a portion of a bottom surface of the drain contact region and the drain field region.

Another embodiment of the present invention provides an electrostatic discharge protection device, which includes a well region of a first conductivity type, two gate structures arranged in parallel on the well region, a drain field region of a second conductivity type in the well region and between the two gate structures, two source field regions of the second conductivity type in the well region and at two sides of the two gate structures opposite to the drain field region, two source contact region of the second conductivity type respectively in the two source field regions, a drain contact region of the first conductivity type in the drain field region, and a plurality of drain doped regions of the first conductivity type in the drain field region and extending at least along edges of the drain contact region that are parallel to the two gate structures.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic plan view of an electrostatic discharge protection device according to one embodiment of the present invention.

FIG. 2 is a schematic cross-sectional view taken along the line A-A′ shown in FIG. 1.

FIG. 3 is a schematic plan view of an electrostatic discharge protection device according to another embodiment of the present invention.

FIG. 4 is a schematic plan view of an electrostatic discharge protection device according to another embodiment of the present invention.

FIG. 5 is a schematic plan view of an electrostatic discharge protection device according to another embodiment of the present invention.

FIG. 6 is a schematic cross-sectional view taken along the line A-A′ shown in FIG. 5.

### DETAILED DESCRIPTION

To provide a better understanding of the present invention to those of ordinary skill in the art, several exemplary embodiments of the present invention will be detailed as follows, with reference to the accompanying drawings using numbered elements to elaborate the contents and effects to be achieved. The accompanying drawings are included to provide a further understanding of the embodiments, and are incorporated in and constitute a part of this specification. Relative dimensions and proportions of parts of the drawings have been shown exaggerated or reduced in size, for the sake of clarity and convenience in the drawings. The same reference signs are generally used to refer to corresponding or similar features in modified and different embodiments. These embodiments are described in sufficient detail to enable those skilled in the art to practice the invention. Other embodiments may be utilized and that structural, logical and electrical changes may be made without departing from the spirit and scope of the present invention.

The electrostatic discharge protection device of the present invention is a lateral double diffusion metal-oxide-semiconductor (LDMOS) device, such as an N-type LDMOS device or a P-type LDMOS device. In the embodiments in the following description, the first conductivity type is P type, the second conductivity type is N type, and the electrostatic discharge protection device is an N-type LDMOS device. The conductivity types in the illustrated embodiments are not limitations to the scope of the present invention. Those skilled in the art may make reasonable design changes according to design needs. For example, in other embodiments, the first conductivity type may be N type, the second conductivity type may be P type, and the electrostatic discharge protection device may be a P-type LDMOS device. These are included in the scope of the present invention.

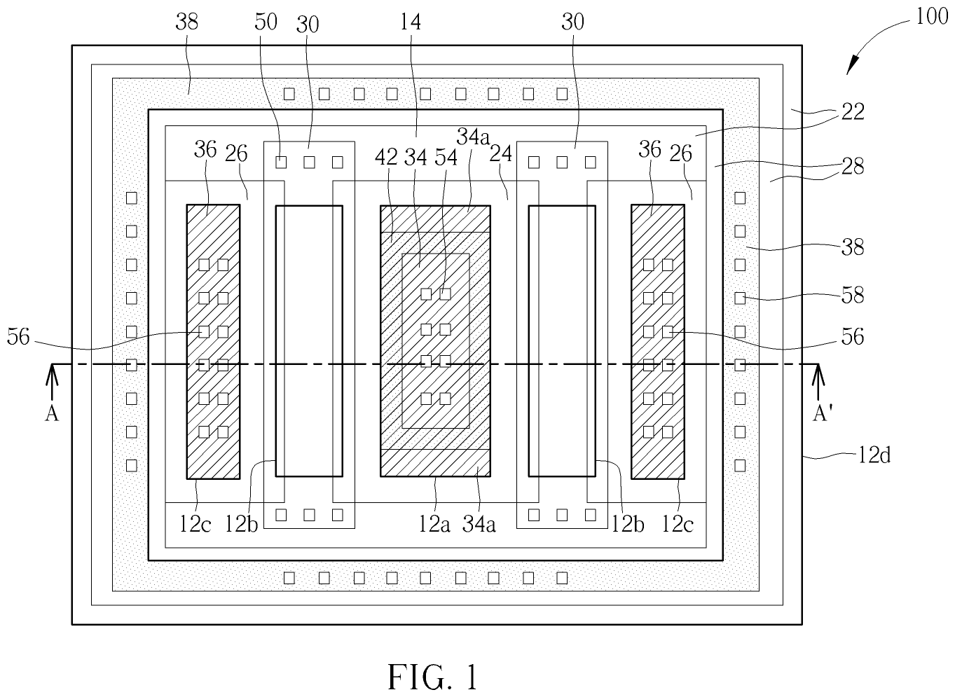

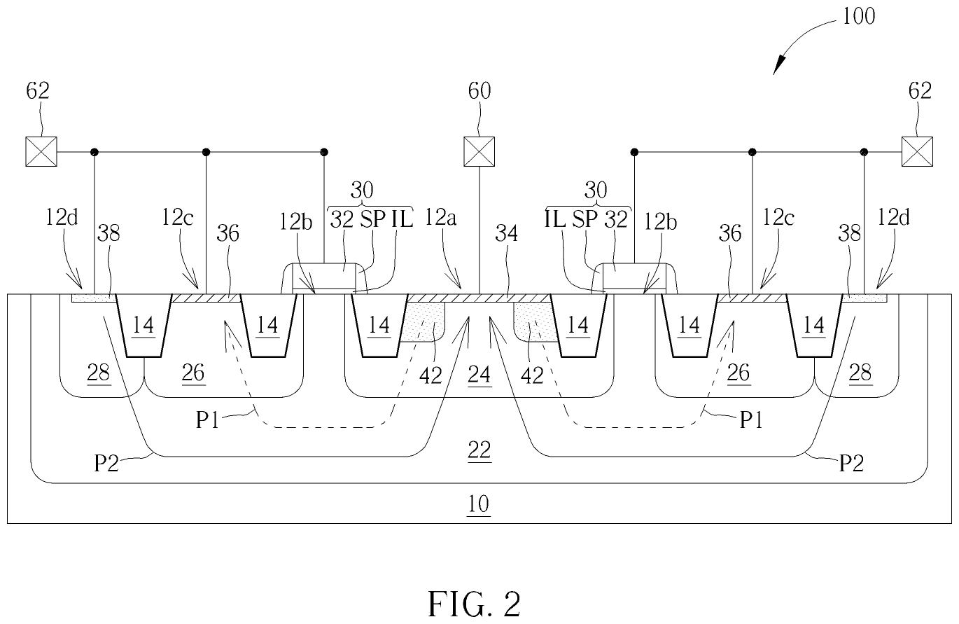

Please refer to FIG. 1 and FIG. 2. FIG. 1 is a schematic plan view, showing a layout of an electrostatic discharge (ESD) protection device 100 according to one embodiment of the present invention. FIG. 2 is a schematic cross-sectional view of the ESD protection device 100 taken along the line A-A′ shown in FIG. 1. The drawings depict the specific features of the present invention, and may omit one or more features, as appropriate, for the sake of simplicity. For example, metal silicide layers, interlayer dielectric layers, etching stop layers, contacts, vias, interconnect structures, or other components of the device may be omitted from the drawing without affecting understanding of the present invention.

The ESD protection device 100 includes a substrate 10, a well region 22 formed in the substrate 10, a drain field region 24 formed in the well region 22, two source field regions 26 formed in the well region 22 and at two sides of the drain field region 24 along the line A-A′. The drain field region 24 and the source field regions 26 are separated from each other by the well region 22, and are not in direct contact with each other. The substrate 10 may be a silicon substrate, a silicon-on-insulator (SOI) substrate, a compound semiconductor substrate, a Group III-V semiconductor substrate, or a strained semiconductor substrate, but is not limited thereto.

The well region 22, the drain field region 24 and the source field regions 26 may be formed by performing an ion implantation process to implant dopants into the substrate 10. The conductivity types of the well region 22, the drain field region 24 and the source field regions 26 are determined by the species of the dopants, wherein the well region 22 is of a first conductivity type, the drain field region 24 and the source field regions 26 are of a second conductivity type, and the first conductivity type and the second conductivity type are complementary. According to an embodiment of the present invention, the first conductivity type is P-type and the second conductivity type is N-type. The well region 22 may also be referred to as a P-well, and the drain field region 24 and the source field regions 26 may be referred as N-field regions. The substrate 10 may include dopants to have a specific conductivity type, such as P-type or N-type.

The ESD protection device 100 further includes an isolation region 14 and a plurality of active regions defined by the isolation region 14 in the substrate 10. The isolation region 14 may be a shallow trench isolation (STI) region, but is not limited thereto. The active regions include, for example, an active region 12a located in the drain field region 24, two active regions 12c respectively located in the source field regions 26, two active regions 12b respectively located between the drain field region 24 and one of the source field regions 26, and an active region 12d around the well region 22. In the plan view as shown in FIG. 1, the active region 12a, the active regions 12b, and the active regions 12c are parallel finger structures arranged along the direction of line A-A′. The active region 12d has a closed ring shape and surrounds the well region 22 where the active region 12a, the active regions 12b, and the active regions 12c are located. In the cross-sectional view as shown in FIG. 2, the depths of the drain field region 24 and the source field regions 26 are approximately the same. The depth of the isolation region 14 is smaller than the depths of the drain field region 24 and the source field regions 26. The portion of the drain field region 24 at the edge of each of the active regions 12b and the portion of the drain field region 24 at the active region 12a are continuously connected without being interrupted by the isolation region 14. Similarly, the portion of the source field region 26 at the other edge of each of the active regions 12b and the portion of the source field region 26 at the neighboring one of the active regions 12c are continuously connected without being interrupted by the isolation region 14.

The active region 12a is completely located in the drain field region 24 and includes a drain contact region 34 and a drain doped region 42. The drain contact region 34 is formed at the surface of the active region 12a by doping dopants of the conductivity type same as the drain field region 24, such as the second conductivity type or N-type. The drain contact region 34 is a heavily doped region having a higher doping concentration than the drain field region 24. The drain doped region 42 is formed by doping dopants of the first conductivity type, such as P-type, and is at a depth larger than the depth of the drain contact region 34 and smaller than the depth of the isolation region 14. More specifically, the drain doped region 42 is formed at least at two sides of the active region 12a (the two sides next to the active regions 12b) under the drain contact region 34, and is between the drain contact region 34 and the isolation region 14. The drain doped region 42 directly contacts sidewalls of the isolation region 14. In some embodiments, as shown in FIG. 1, the drain doped region 42 has a closed ring shape and completely surrounds the drain contact region 34. In some embodiments, the active region 12a further includes doped regions 34a at the two ends perpendicular to the direction of line A-A′. The doped regions 34a are respectively between the drain doped region 42 and the isolation region 14, and have the conductivity type same as the drain contact region 34. A plurality of contact structures 54 may be formed on the drain contact region 34 to electrically connect the drain contact region 34 and the drain doped region 42 to outside, such as a power line (Vdd), or an input terminal that is connected to a contact pad 60. In some embodiments, the contact pad 60 is an input/output pad.

The active regions 12c are completely located in the source field regions 26, respectively. The surface portion of each of the active regions 12c includes a source contact region 36 that is formed by doping dopants of the conductivity type same the source field regions 26, such as the second conductivity type or N-type. The source contact region 36 is a heavily doped region having a higher doping concentration than the source field regions 26. A plurality of contact structures 56 may be formed on the source contact region 36 to electrically connect the source contact region 36 to outside, such as a ground line (Vss), or an input terminal that is connected to a contact pad 62. In some embodiments, the contact pad 62 is a ground pad.

The active regions 12b are respectively between the drain field region 24 and one of the source field regions 26. The two side portions of each of the active regions 12b respectively partially overlap the drain field region 24 and one of the source field regions 26, and are therefore referred to as parts of the drain field region 24 and the source field region 26. The middle portion of each of the active regions 12b is a part of the well region 22.

The ESD protection device 100 further includes two gate structures 30 arranged in parallel on the well region 22, respectively between the drain field region 24 and one of the source field regions 26, and partially overlapping the active regions 12b. According to an embodiment of the present invention, each of the gate structures 30 includes an electrode portion 32, spacers SP on sidewalls of the electrode portion 32, and a dielectric layer IL between the electrode portion 32 and the substrate 10. The electrode portion 32 includes a semiconductor material or a conductive material, such as polycrystalline silicon or metal, but is not limited thereto. The dielectric layer IL and the spacers SP respectively include a dielectric material, such as silicon oxide, silicon nitride, or a combination thereof, but are not limited thereto. As shown in FIG. 2, along the direction of line A-A′, the widths of the electrode portions 32 are larger than the widths of the active regions 12b. The electrode portions 32 respectively partially overlap the drain field region 24, the source field region 26, and the isolation region 14 at two sides of the active regions 12b. A plurality of contact structures 50 may be formed on the gate structures 30 to electrically connect the gate structures 30 to outside, such as a contact pad 62.

In some embodiments, the ESD protection device 100 further includes a well contact region 38 formed at the surface portion of the active region 12d, and a field region 28 between the well contact region 38 and the well region 22. The well contact region 38 and the field region 28 have dopants of the conductivity type same as the well region 22, such as the first conductivity type or P-type. The doping concentration of the well contact region 38 is higher than the field region 28, and the doping concentration of the field region 28 is higher than the well region 22. The well contact region 38 is a heavily doped region. In some embodiments, the doping concentration of the drain doped region 42 is lower than the doping concentration of the well contact region 38 and higher than the field region 28. In the plan view as shown in FIG. 1, the well contact region 38 has a closed ring shape and surrounds the well region 22 where the drain field region 24, the source field region 26, the active region 12a, the active regions 12b, and the active regions 12c are located. A plurality of contact structures 58 may be formed on the well contact region 38 to electrically connect the well contact region 38 to outside, such as the contact pad 62. In the cross-sectional view as shown in FIG. 2, the depths of the field region 28, the drain field region 24, and the source field regions 26 are approximately the same.

The accumulated electrostatic charges may be positive charges or negative charges, which means that the ESD pulse occurring on the integrated circuit chip may be a positive voltage or a negative voltage, resulting in a forward or reverse ESD current, respectively. The ESD protection device 100 of the present invention, by forming the drain doped region 42 under the drain contact region 34 as taught by the present invention, may immediately and effectively bypass whether a forward ESD current or a reverse ESD current to outside instead of injecting into the internal circuits, so that the internal circuits may be well protected from damages caused by the ESD current.

More specifically speaking, as shown in FIG. 2, the drain doped region 42 is formed under the drain contact region 34 and adjacent to the isolation region 14 at two sides of the drain contact region 34, and between bottom surfaces of the two side portions of the drain contact region 34 and the drain field region 24. The bottom surfaces of the two side portions of the drain contact region 34 are covered and separated from the drain field region 24 by the drain doped region 42 while the bottom surface of the middle portion of the drain contact region 34 is exposed from the drain doped region 42 and directly contacts the drain field region 24.

In this way, for example, when the ESD protection device 100 is an N-type LDMOS device (the drain contact region 34 and the drain field region 24 are N-type, the well region 22 is P-type) and a positive ESD voltage occurs at the contact pad 60, a parasitic PNPN silicon controlled rectifier (SCR) formed by the drain doped region 42, the drain field region 24, the well region 22 under the gate structure 30, the source field region 26 and the source contact region 36 may be triggered immediately to provide a current path P1 to discharge the ESD current form the contact pad 60 to the contact pad 62 and then to the external circuits. On the other hand, when a negative ESD voltage occurs at the contact pad 60, a parasitic PN diode formed by the source contact region 36, the source field region 26, the drain field region 24 and drain contact region 34 may be triggered immediately to provide a current path P2 to discharge the ESD current form the contact pad 62 to the contact pad 60 and then to the external circuits. Overall, the ESD protection device 100 provided by the present invention has improved performance in both HBM and MM stress tests.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

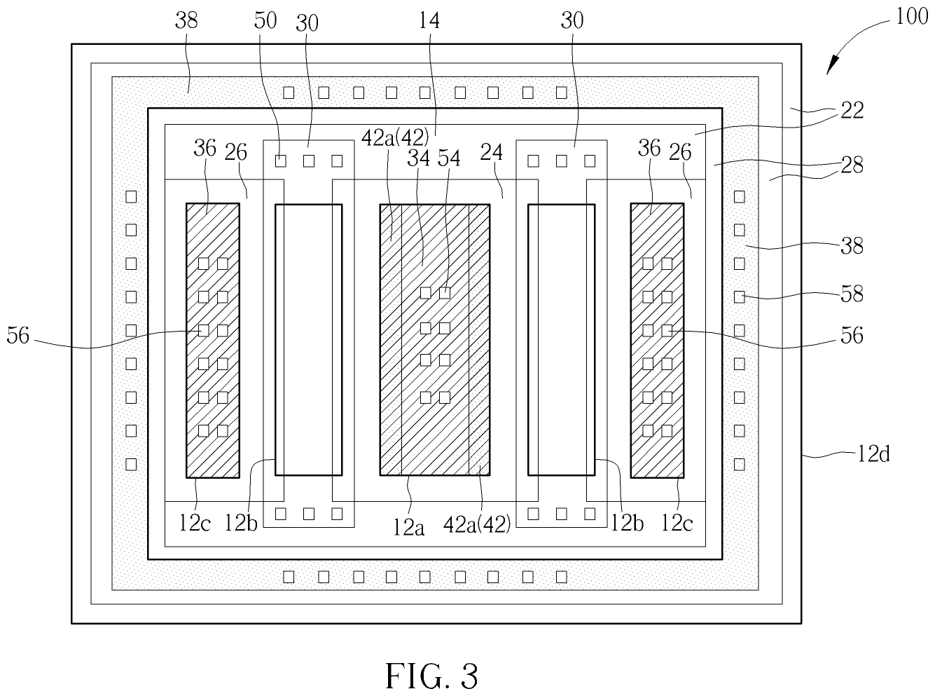

Implementations of the present invention are not limited to the previous embodiments. The ESD protection device 100 provided by the present invention may be modified according to design needs. Please refer to FIG. 3, which is a schematic plan view of an ESD protection device 100 according to another embodiment of the present invention. As shown in FIG. 3, the drain doped region 42 includes at least two elongated portions 42a respectively under the two side portions of the drain contact region 34 adjacent to the active regions 12b. The two elongated portions 42a are respectively between the drain contact region 34 and the isolation region 14, extending along the two edges of the active region 12a (also the edges of the drain contact region 34) that are parallel to the gate structures 30. The other two edges of the drain contact region 34 are flush with the edges of the active region 12b.

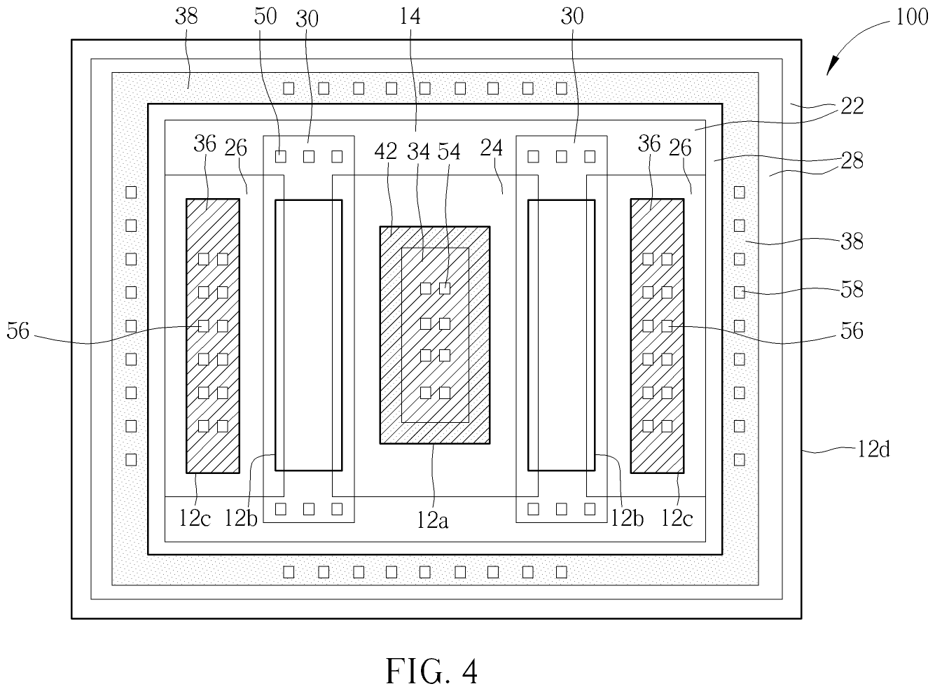

Please refer to FIG. 4, which is a schematic plan view of an ESD protection device 100 according to another embodiment of the present invention. As shown in FIG. 4, the drain doped region 42 has a closed ring shape along the four edges of the active region 12a and completely surrounds the drain contact region 34. All of the four edges of the drain doped region 42 border the isolation region 14.

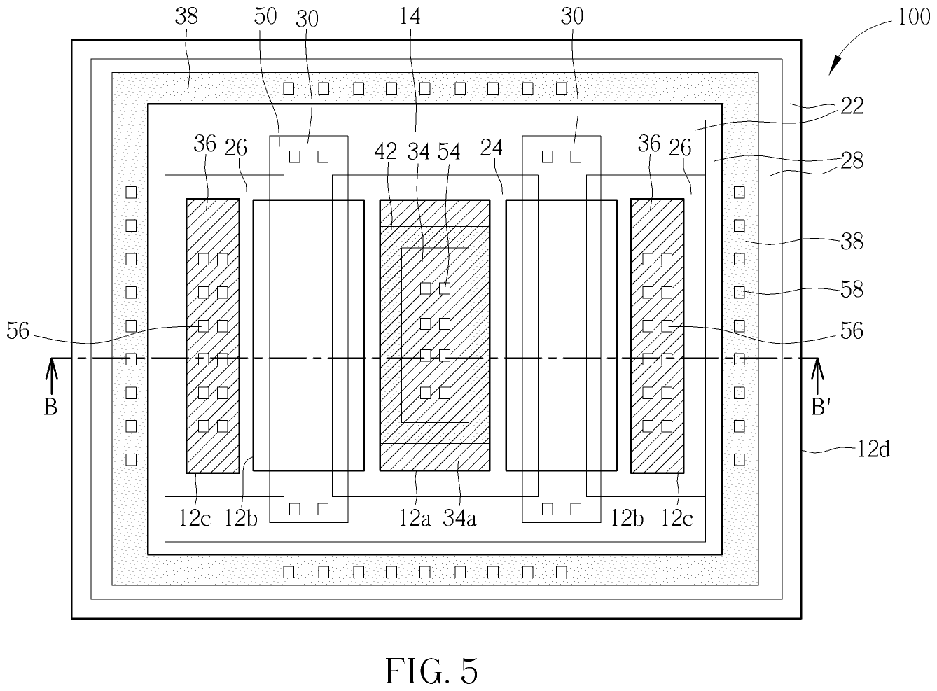

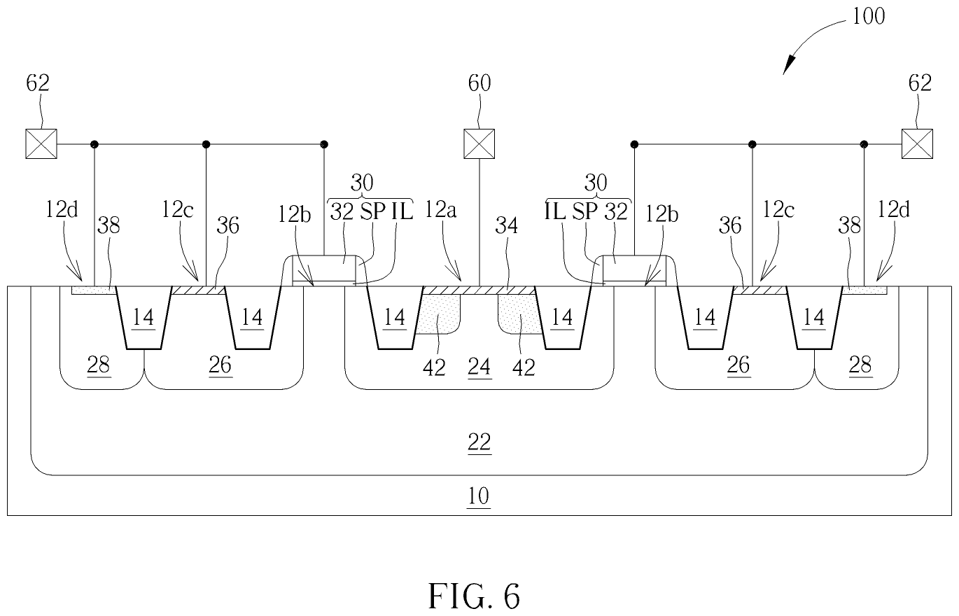

Please refer to FIG. 5 and FIG. 6. FIG. 5 is a schematic plan view of an electrostatic discharge protection device according to another embodiment of the present invention. FIG. 6 is a schematic cross-sectional view taken along the line A-A′ shown in FIG. 5. In this embodiment, along the direction of line A-A′, the width of the electrode portion 32 of the gate structure 30 is smaller than the width of the active region 12b. The two sides of the electrode portion 32 respectively overlap with the drain field region 24 and the source field region 26, but do not overlap with the isolation region 14.

In conclusion, the ESD protection device 100 provided by the present invention, including the drain doped region 42 under the drain contact region 34 as taught by the present invention, may immediately and effectively bypass whether a forward ESD current caused by positive ESD voltage or a reverse ESD current caused by negative ESD voltage to outside instead of injecting into the internal circuits, so that the internal circuits may be well protected from damages caused by the ESD current.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electrostatic discharge protection device, comprising:
a substrate;
a well region of a first conductivity type in the substrate;
a drain field region and a source field region of a second conductivity type in the well region;
a gate structure on the well region and between the drain field region and the source field region;
a drain contact region and a source contact region of the second conductivity type respectively in the drain field region and the source field region;
a first isolation region in the drain field region and between the drain contact region and the gate structure; and
a drain doped region of the first conductivity in the drain field region and between a portion of a bottom surface of the drain contact region and the drain field region.

2. The electrostatic discharge protection device according to claim 1, wherein the drain doped region is in direct contact with a sidewall of the first isolation region.

3. The electrostatic discharge protection device according to claim 1, wherein a depth of the drain doped region is larger than a depth of the drain contact region.

4. The electrostatic discharge protection device according to claim 1, wherein a depth of the drain doped region is smaller than a depth of the first isolation region.

5. The electrostatic discharge protection device according to claim 1, wherein a depth of the first isolation region is smaller than a depth of the drain field region.

6. The electrostatic discharge protection device according to claim 1, wherein the gate structure partially overlaps the drain field region and the source field region.

7. The electrostatic discharge protection device according to claim 1, wherein the gate structure partially overlaps the first isolation region.

8. The electrostatic discharge protection device according to claim 1, further comprising a second isolation region in the source field region and between the source contact region and the gate structure.

9. The electrostatic discharge protection device according to claim 8, wherein the gate structure partially overlaps the second first isolation region.

10. The electrostatic discharge protection device according to claim 1, wherein the drain contact region and the drain doped region are electrically coupled to an input/output pad, and the well region, the gate structure and the source contact region are electrically coupled to a ground terminal.

11. The electrostatic discharge protection device according to claim 1, wherein the first conductivity type is P type and the second conductivity type is N type.

12. An electrostatic discharge protection device, comprising:
a well region of a first conductivity type;
two gate structures arranged in parallel on the well region;
a drain field region of a second conductivity type in the well region and between the two gate structures;
two source field regions of the second conductivity type in the well region and at two sides of the two gate structures opposite to the drain field region;
two source contact region of the second conductivity type respectively in the two source field regions;
a drain contact region of the first conductivity type in the drain field region; and
a plurality of drain doped regions of the first conductivity type in the drain field region and extending at least along edges of the drain contact region that are parallel to the two gate structures.

13. The electrostatic discharge protection device according to claim 12, wherein the drain doped regions has a closed ring shape completely surrounding the drain contact region.

14. The electrostatic discharge protection device according to claim 12, wherein the drain doped regions comprise two long strip portions parallel to each other.

15. The electrostatic discharge protection device according to claim 12, wherein each of the two gate structures partially overlaps the drain field region and one of the two source field regions.

16. The electrostatic discharge protection device according to claim 12, further comprising a first isolation region surrounding the drain contact region and the drain doped regions.

17. The electrostatic discharge protection device according to claim 16, wherein each of the two gate structures partially overlaps the first isolation region.

18. The electrostatic discharge protection device according to claim 12, further comprising two second isolation regions respectively surrounding the two source contact region.

19. The electrostatic discharge protection device according to claim 18, wherein the two gate structures respectively partially overlap one of the two second isolation regions.

20. The electrostatic discharge protection device according to claim 12, further comprising a well contact region of the first conductivity type surrounding the well region.
